(19) United States
(12) Patent Application Publication
(10) Pub. No.: US 2025/0346992 A1
(43) Pub. Date: Nov. 13, 2025

(54) FILM FORMING METHOD AND FILM FORMING APPARATUS

(71) Applicant: Tokyo Electron Limited, Tokyo (JP)

(72) Inventors: Jun OGAWA, Yamanashi (JP); Sung Duk SON, Gyeonggi-do (KR)

(21) Appl. No.: 19/191,504

(22) Filed: Apr. 28, 2025

(30) Foreign Application Priority Data
May 10, 2024 (JP) 2024-077551

(51) Int. Cl. C23C 16/04; C23C 16/24; C23C 16/34; C23C 16/455

(52) U.S. Cl. CPC C23C 16/045; C23C 16/24; C23C 16/345; C23C 16/45544; C23C 16/45553

(57) ABSTRACT

A film forming method includes: (a) preparing a substrate having a recess in a surface thereof; (b) forming a silicon nitride film in the recess; (C) forming an amorphous silicon film in the recess; (d) removing the amorphous silicon film; and (e) filling the recess with the silicon nitride film after the (d) removing the amorphous silicon film. The amorphous silicon film is formed such that step coverage of the amorphous silicon film is lower than step coverage of the silicon nitride film, and the (c) forming the amorphous silicon film is performed one or more times during the (b) forming the silicon nitride film.

### CROSS-REFERENCE TO RELATED APPLICATION

This application is based on and claims priority to Japanese Patent Application No. 2024-077551, filed on May 10, 2024, the entire contents of which are incorporated herein by reference.

### TECHNICAL FIELD

The present disclosure relates to a film forming method and a film forming apparatus.

### BACKGROUND

A technique by which a trench formed in a surface of a substrate is filled with a silicon nitride film is disclosed (see Japanese Laid-Open Patent Publication No. 2017-139306, for example).

### SUMMARY

A film forming method according to one aspect of the present disclosure includes: (a) preparing a substrate having a recess in a surface thereof; (b) forming a silicon nitride film in the recess; (c) forming an amorphous silicon film in the recess; (d) removing the amorphous silicon film; and (e) filling the recess with the silicon nitride film after the (d) removing the amorphous silicon film. The amorphous silicon film is formed such that step coverage of the amorphous silicon film is lower than step coverage of the silicon nitride film, and the (c) forming the amorphous silicon film is performed one or more times during the (b) forming the silicon nitride film.

### BRIEF DESCRIPTION OF THE DRAWINGS

FIG. 1 is a cross-sectional view (1) illustrating a film forming method according to an embodiment;

FIG. 2 is a cross-sectional view (2) illustrating the film forming method according to the embodiment;

FIG. 3 is a cross-sectional view (3) illustrating the film forming method according to the embodiment;

FIG. 4 is a cross-sectional view (4) illustrating the film forming method according to the embodiment;

FIG. 5 is a cross-sectional view (5) illustrating the film forming method according to the embodiment;

FIG. 6 is a cross-sectional view (6) illustrating the film forming method according to the embodiment;

FIG. 7 is a cross-sectional view (7) illustrating the film forming method according to the embodiment;

FIG. 8 is a cross-sectional view (8) illustrating the film forming method according to the embodiment;

FIG. 9 is a diagram illustrating an example of a relationship between the number of ALD cycles and the thickness of a silicon nitride film;

FIG. 10 is a vertical sectional view illustrating a film forming apparatus according to an embodiment; and

FIG. 11 is a horizontal sectional view illustrating the film forming apparatus according to the embodiment.

### DETAILED DESCRIPTION

Hereinafter, non-limiting embodiments of the present disclosure will be described with reference to the accompanying drawings. Throughout the attached drawings, the same or corresponding members or components are designated by the same or corresponding reference numerals, and a duplicate description thereof will be omitted.

### Film Forming Method

A film forming method according to an embodiment will be described with reference to FIG. 1 to FIG. 9. FIG. 1 to FIG. 8 are cross-sectional views illustrating the film forming method according to the embodiment.

First, as illustrated in FIG. 1, a substrate 101 is prepared. The substrate 101 is a semiconductor substrate such as a silicon substrate. The substrate 101 has a recess 102 in a surface thereof. The recess 102 includes a bottom surface 102a, an inner side surface 102b, and a top surface 102c. The recess 102 is, for example, a trench. The recess 102 may be a hole. An insulating film 103 may be provided on the surface of the substrate 101. The insulating film 103 covers the bottom surface 102a, the inner side surface 102b, and the top surface 102c. The insulating film 103 is, for example, a silicon oxide film.

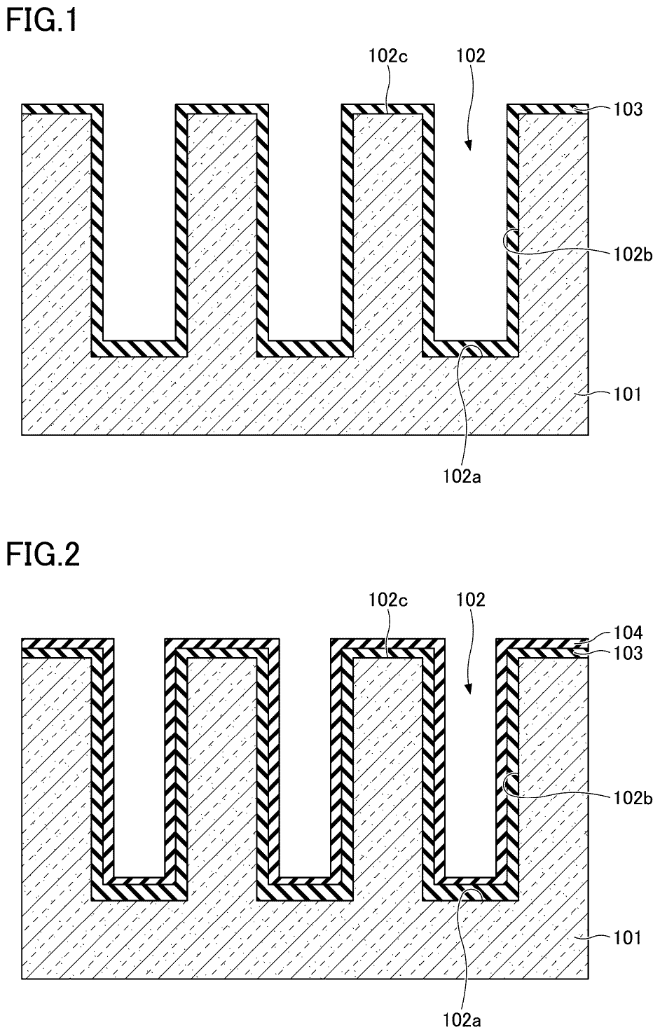

Next, as illustrated in FIG. 2, a silicon nitride film 104 is formed in the recess 102. The silicon nitride film 104 is formed so as to cover the bottom surface 102a, the inner side surface 102b, and the top surface 102c. The silicon nitride film 104 may be conformally formed along the bottom surface 102a, the inner side surface 102b, and the top surface 102c.

The silicon nitride film 104 can be formed by, for example, atomic layer deposition (ALD) in which dichlorosilane (DCS) and ammonia (NH₃) are alternately supplied to the substrate 101 maintained at a first temperature. When the silicon nitride film 104 is formed by atomic layer deposition, the silicon nitride film 104 tends to be formed conformally along the bottom surface 102a, the inner side surface 102b, and the top surface 102c. The first temperature may be 450° C. or more and 650° C. or less, and is, for example, 550° C. In atomic layer deposition, thermal nitridation is preferably used.

When thermal nitridation is used, nitridation of an amorphous silicon film 105, which will be described later, by ammonia can be reduced as compared to when plasma nitridation is used. In atomic layer deposition, purging may be performed between the supply of dichlorosilane and the supply of ammonia. Dichlorosilane is an example of a first silicon-containing gas, and ammonia is an example of a nitriding gas.

When a predetermined period of time has elapsed, the formation of the silicon nitride film 104 is stopped. The predetermined period of time may be a period of time set so as to ensure that the silicon nitride film 104 does not completely close off the opening of the recess 102.

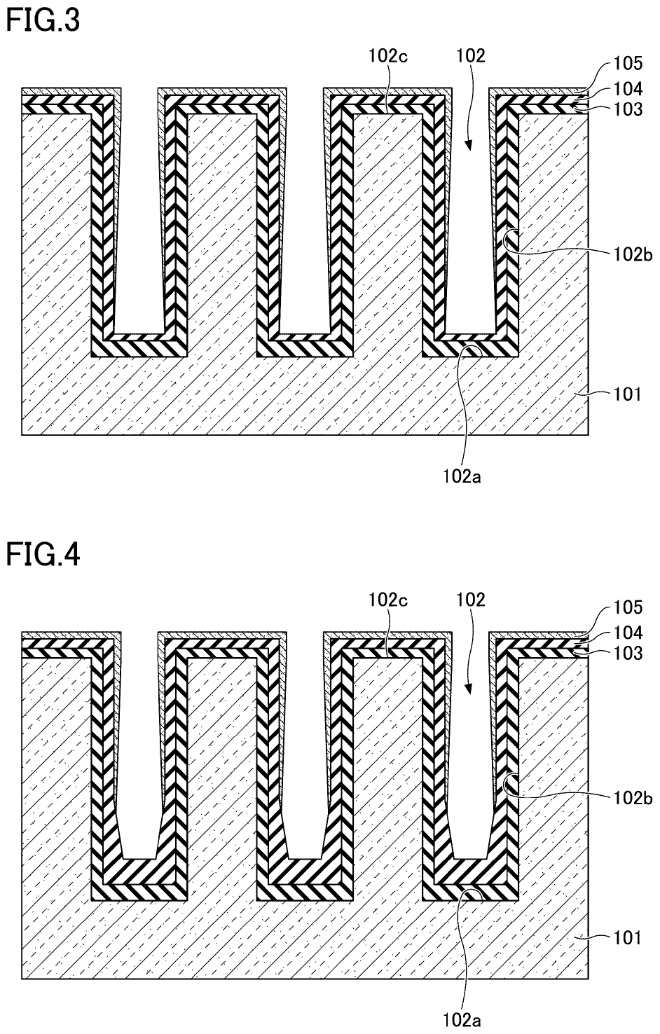

Next, as illustrated in FIG. 3, an amorphous silicon film 105 is formed in the recess 102. The amorphous silicon film 105 is formed such that the step coverage of the amorphous silicon film 105 is lower than the step coverage of the silicon nitride film 104. The step coverage is defined as a value (percentage) obtained by dividing the thickness of a film formed on the inner side surface 102b at the intermediate position in the depth direction of the recess 102 by the thickness of the film formed on the inner side surface 102b at the upper end position in the depth direction of the recess 102. The amorphous silicon film 105 may be formed so as to cover an upper portion of the inner side surface 102b and the top surface 102c. In this case, when the silicon nitride film 104 is further formed after the amorphous silicon film 105 is formed, the silicon nitride film is easily formed on the bottom surface 102a. The amorphous silicon film 105 may contain oxygen as an impurity. In a case where the amorphous silicon film 105 contains oxygen therein, the number of ALD cycles X2, which will be described later, increases as compared to when the amorphous silicon film 105 does not contain oxygen therein.

The amorphous silicon film 105 can be formed by, for example, chemical vapor deposition (CVD) in which disilane (Si₂H₆) and dinitrogen monoxide (N₂O) are simultaneously supplied to the substrate 101 maintained at the first temperature. When the amorphous silicon film 105 is formed by chemical vapor deposition, the amorphous silicon film 105 tends to be formed so as to cover the upper portion of the inner side surface 102b and the top surface 102c. Maintaining the substrate 101 at the first temperature allows the silicon nitride film 104 and the amorphous silicon film 105 to be continuously formed without changing the temperature, thereby improving the productivity. The chemical vapor deposition may include supplying dinitrogen monoxide without supplying disilane to the substrate 101 after simultaneously supplying disilane and dinitrogen monoxide to the substrate 101. In this case, oxide (O) is adsorbed on the surface of the amorphous silicon film 105, and thus the number of ALD cycles X2, which will be described later, increases.

When a predetermined period of time has elapsed, the formation of the amorphous silicon film 105 is stopped. The predetermined period of time may be a period of time during which the amorphous silicon film 105 is not formed on the silicon nitride film 104 formed on the bottom surface 102a. Disilane is an example of a second silicon-containing gas, and dinitrogen monoxide is an example of an impurity-containing gas.

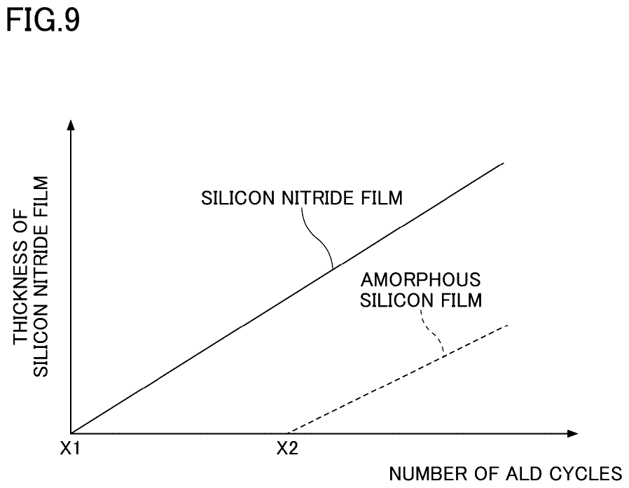

Next, the formation of the silicon nitride film 104 in the recess 102 is resumed. FIG. 9 is a diagram illustrating an example of a relationship between the number of ALD cycles and the thickness of the silicon nitride film 104. In FIG. 9, the horizontal axis represents the number of ALD cycles, and the vertical axis represents the thickness of the silicon nitride film 104. In FIG. 9, a solid line indicates a case in which the silicon nitride film 104 is further formed on the silicon nitride film 104, and a dashed line indicates a case in which the silicon nitride film 104 is formed on the amorphous silicon film 105. In FIG. 9, X1 represents the number of ALD cycles in which the silicon nitride film 104 starts to be further formed on the silicon nitride film 104 after the formation of the silicon nitride film 104 is resumed. In addition, X2 represents the number of ALD cycles in which the silicon nitride film 104 starts to be formed on the amorphous silicon film 105 after the formation of the silicon nitride film 104 is resumed. As illustrated in FIG. 9, the relationship of X1<X2 is satisfied. Therefore, before the silicon nitride film 104 is formed on the amorphous silicon film 105, the silicon nitride film 104 is selectively further formed on the silicon nitride film 104. As a result, as illustrated in FIG. 4, the silicon nitride film 104 is formed in a substantially V-shape in the recess 102. In particular, by setting the number of ALD cycles when the silicon nitride film 104 is formed to be less than or equal to X2, the silicon nitride film 104 can be further formed only on the silicon nitride film 104 without being formed on the amorphous silicon film 105.

When a predetermined period of time has elapsed, the formation of the silicon nitride film 104 is stopped. The predetermined period of time may be a period of time during which the silicon nitride film 104 is not formed on the amorphous silicon film 105. That is, before the silicon nitride film 104 is formed on the amorphous silicon film 105, the formation of the amorphous silicon film 105 may be started.

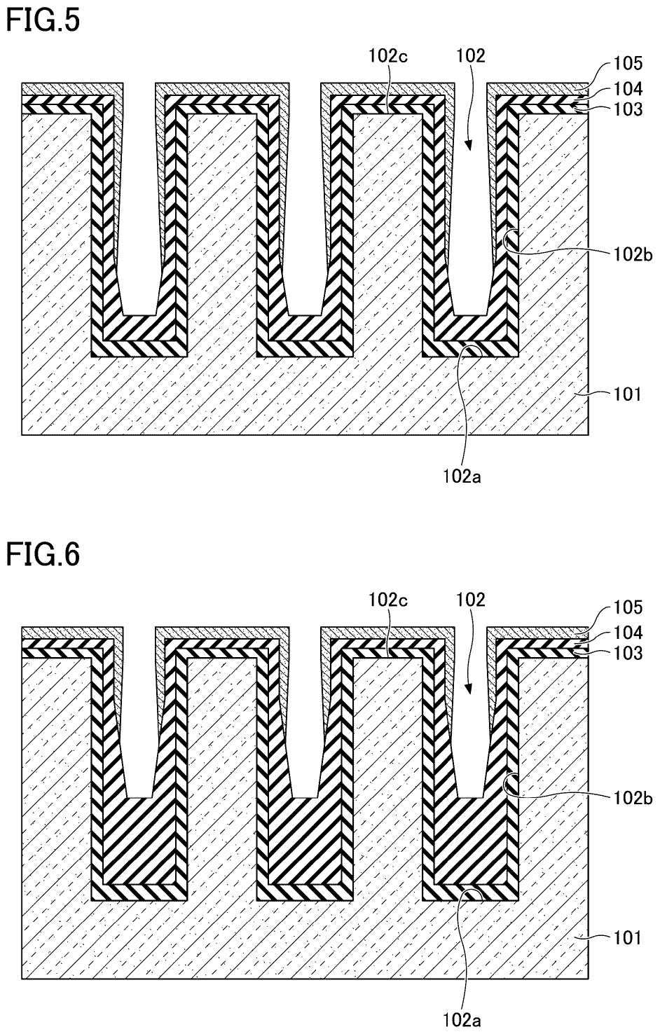

Next, as illustrated in FIG. 5, the amorphous silicon film 105 is further formed in the recess 102. The amorphous silicon film 105 is formed in the same manner as in FIG. 3.

When a predetermined period of time has elapsed, the formation of the amorphous silicon film 105 is stopped. The predetermined period of time may be a period of time during which the amorphous silicon film 105 is not formed on the silicon nitride film 104 formed on the bottom surface 102a.

Next, the formation of the silicon nitride film 104 in the recess 102 is resumed. The silicon nitride film 104 is formed in the same manner as in FIG. 4. As a result, as illustrated in FIG. 6, the silicon nitride film 104 is formed from a deep position to a shallow position of the recess 102, and the silicon nitride film 104 is formed in a substantially V shape.

When a predetermined period of time has elapsed, the formation of the silicon nitride film 104 is stopped. The predetermined period of time may be a period of time during which the silicon nitride film 104 is not formed on the amorphous silicon film 105. In this manner, the amorphous silicon film 105 is formed two times during the formation of the silicon nitride film 104. For example, if the aspect ratio of the recess 102 is low, the amorphous silicon film 105 may be formed only once during the formation of the silicon nitride film 104. For example, if the aspect ratio of the recess 102 is high, the amorphous silicon film 105 is preferably formed two times or more during the formation of the silicon nitride film 104.

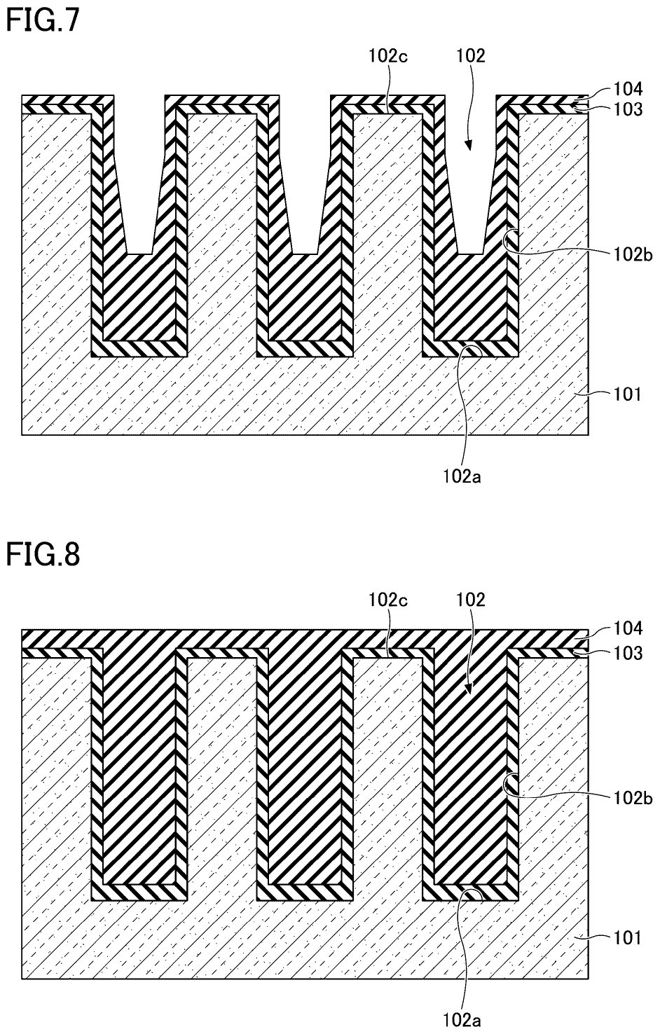

Next, as illustrated in FIG. 7, the amorphous silicon film 105 is selectively etched and removed. For example, the amorphous silicon film 105 can be selectively etched and removed by supplying an etching gas having an etching rate for the amorphous silicon film 105 higher than an etching rate for the silicon nitride film 104 to the substrate 101 maintained at the first temperature. By maintaining the substrate 101 at the first temperature, the amorphous silicon film 105 can be removed continuously without changing the temperature of the substrate 101 after the silicon nitride film 104 is formed. Thus, the productivity is improved. The etching gas is, for example, chlorine (Cl₂).

When a predetermined period of time has elapsed, the etching of the amorphous silicon film 105 is stopped. The predetermined period of time may be longer than a period of time during which the amorphous silicon film 105 is removed.

Next, as illustrated in FIG. 8, the recess 102 is filled with the silicon nitride film 104. The silicon nitride film 104 is formed in the same manner as in FIG. 4. In this case, the silicon nitride film 104 can be formed on the silicon nitride film 104 formed in the substantially V shape. Therefore, the occurrence of voids and seams when the recess 102 is filled with the silicon nitride film 104 can be reduced.

As described above, in the film forming method according to the embodiment, before the recess 102 is filled with the silicon nitride film 104, first, a process of forming the amorphous silicon film 105 in the recess 102 is performed one or more times during a process of forming the silicon nitride film in the recess 102. The amorphous silicon film 105 is formed such that the step coverage of the amorphous silicon film 105 is lower than that of the silicon nitride film 104. In this case, the silicon nitride film 104 is formed from a deep position to a shallow position of the recess 102, and the silicon nitride film 104 is formed in a substantially V shape.

Next, the amorphous silicon film 105 is removed, and the recess 102 is filled with the silicon nitride film 104. In this case, the silicon nitride film 104 can be formed on the silicon nitride film 104 formed in the substantially V shape. Accordingly, the occurrence of voids and seams when the recess 102 is filled with the silicon nitride film 104 can be reduced.

### Film Forming Apparatus

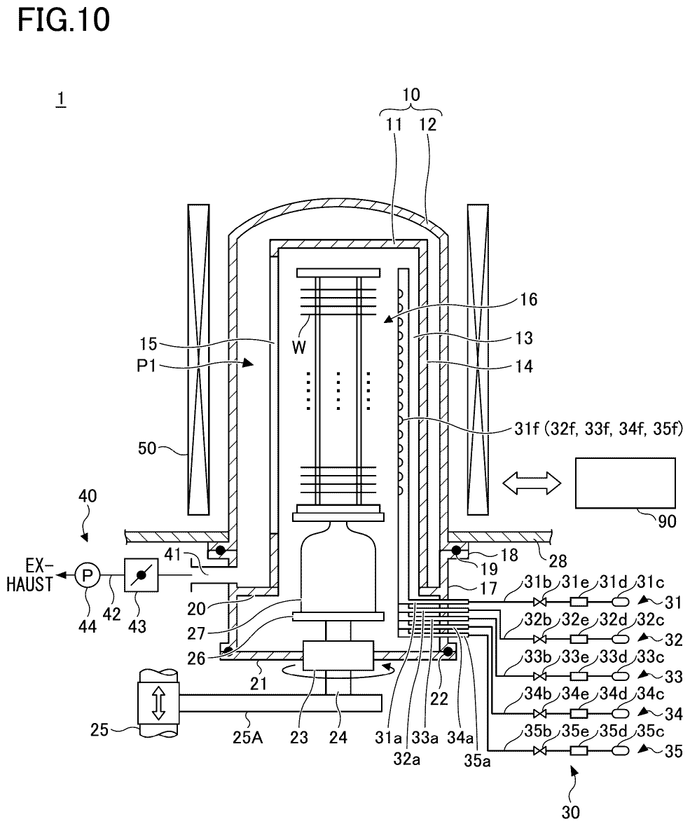

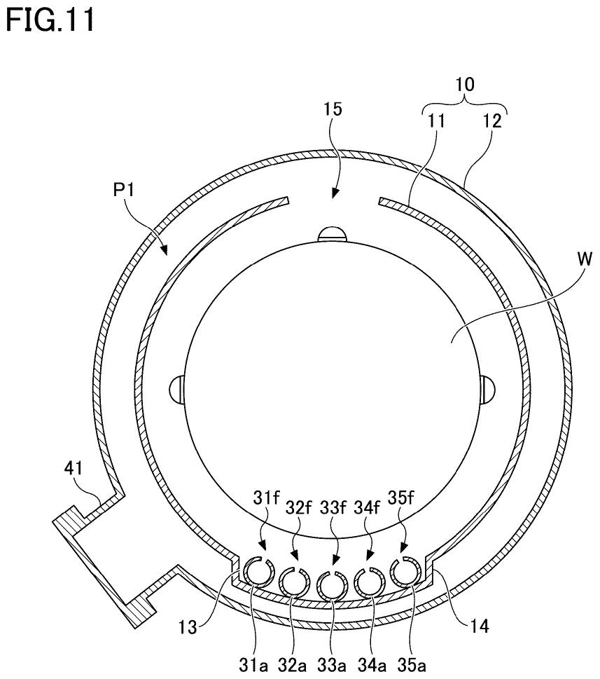

A film forming apparatus 1 according to an embodiment will be described with reference to FIG. 10 and FIG. 11. FIG. 10 is a vertical sectional view illustrating the film forming apparatus 1 according to the embodiment. FIG. 11 is a horizontal sectional view illustrating the film forming apparatus 1 according to the embodiment.

The film forming apparatus 1 is a batch-type apparatus that simultaneously performs processes on a plurality of substrates W. The substrates W are, for example, semiconductor wafers. The film forming apparatus 1 includes a processing chamber 10, a gas supply 30, an exhaust 40, a heater 50, and a controller 90.

The inside of the processing chamber 10 can be depressurized. The processing chamber 10 accommodates the substrates W. The processing chamber 10 includes an inner tube 11 and an outer tube 12. The inner tube 11 has a cylindrical shape with a ceiling and an open lower end. The outer tube 12 has a cylindrical shape with a ceiling and an open lower end and covers the outer side of the inner tube 11. The inner tube 11 and the outer tube 12 are formed of a heat resistant material such as quartz. The inner tube 11 and the outer tube 12 are arranged to be concentric to form a double-tube structure.

An accommodating section 13 for accommodating gas nozzles along the longitudinal direction (vertical direction) of the inner tube 11 is formed on the side wall of the inner tube 11. For example, the side wall of the inner tube 11 partially protrudes outward to form a protrusion 14, and the inner space of the protrusion 14 is formed as the accommodating section 13.

A rectangular opening 15 is formed in the side wall of the inner tube 11 along the longitudinal direction of the inner tube 11. The opening 15 faces the accommodating section 13.

The opening 15 is a gas exhaust port configured to exhaust the gas that is in the inner tube 11. The length of the opening 15 is the same as the length of a boat 16. Alternatively, the length of the opening 15 is greater than the length of the boat 16 so that the opening 15 extends further in the vertical direction than the boat 16.

The lower end of the processing chamber 10 is supported by a cylindrical manifold 17. The manifold 17 is formed of, for example, stainless steel. A flange 18 is formed on the upper end of the manifold 17. The flange 18 supports the lower end of the outer tube 12. A seal member 19 such as an O-ring is provided between the flange 18 and the lower end of the outer tube 12. Thus, the inside of the outer tube 12 is maintained airtight.

An annular support 20 is provided on the inner wall at an upper portion of the manifold 17. The support 20 supports the lower end of the inner tube 11. A lid 21 is airtightly attached to an opening at the lower end of the manifold 17 via a seal member 22 such as an O-ring. Thus, the opening at the lower end of the processing chamber 10, that is, the opening of the manifold 17, is closed airtight. The lid 21 is formed of, for example, stainless steel.

A rotating shaft 24 is provided so as to penetrate a center portion of the lid 21 via a magnetic fluid seal 23. A lower portion of the rotating shaft 24 is rotatably supported on an arm 25A of an elevator mechanism 25 including a boat elevator.

A rotary plate 26 is provided on the upper end of the rotating shaft 24. The boat 16 configured to hold the substrates W via a thermal insulation base 27 formed of quartz is placed on the rotary plate 26. The boat 16 rotates by rotating the rotating shaft 24. The boat 16 moves up and down integrally with the lid 21 by raising and lowering the elevator mechanism 25. Thus, the boat 16 is inserted into and removed from the processing chamber 10. The boat 16 can be accommodated inside the processing chamber 10. The boat 16 holds the plurality of (for example, 50 to 150) substrates W at intervals in a vertically stacked manner. The boat 16 holds the plurality of substrates W in an approximately horizontal state at intervals in the vertical direction.

The gas supply 30 is configured to introduce various processing gases into the inner tube 11. The gas supply 30 includes a DCS supply 31, a disilane supply 32, an ammonia supply 33, a dinitrogen monoxide supply 34, and a chlorine supply 35.

The DCS supply 31 includes a gas supply pipe 31a inside the processing chamber 10, and a supply passage 31b outside the processing chamber 10. The supply passage 31b is provided with a DCS source 31c, a mass flow controller 31d, a valve 31e in this order from an upstream side to a downstream side along a gas flowing direction. Thus, a supply timing of dichlorosilane from the DCS source 31c is controlled by the valve 31e, and the flow of dichlorosilane is adjusted to a predetermined flow rate by the mass flow controller 31d. Dichlorosilane flows from the supply passage 31b to the gas supply pipe 31a, and is discharged from the gas supply pipe 31a into the processing chamber 10.

The disilane supply 32 includes a gas supply pipe 32a inside the processing chamber 10, and a supply passage 32b outside the processing chamber 10. The supply passage 32b is provided with a disilane source 32c, a mass flow controller 32d, and a valve 32e in this order from an upstream side to a downstream side along a gas flowing direction. Thus, a supply timing of disilane from the disilane source 32c is controlled by the valve 32e, and the flow of disilane is adjusted to a predetermined flow rate by the mass flow controller 32d. Disilane flows from the supply passage 32b to the gas supply pipe 32a, and is discharged from the gas supply pipe 32a into the processing chamber 10.

The ammonia supply 33 includes a gas supply pipe 33a inside the processing chamber 10, and a supply passage 33b outside the processing chamber 10. The supply passage 33b is provided with an ammonia source 33c, a mass flow controller 33d, and a valve 33e in this order from an upstream side to a downstream side along a gas flowing direction.

Thus, a supply timing of ammonia from the ammonia source 33c is controlled by the valve 33e, and the flow of ammonia is adjusted to a predetermined flow rate by the mass flow controller 33d. Ammonia flows from the supply passage 33b to the gas supply pipe 33a, and is discharged from the gas supply pipe 33a into the processing chamber 10.

The dinitrogen monoxide supply 34 includes a gas supply pipe 34a inside the processing chamber 10, and a supply passage 34b outside the processing chamber 10. The supply passage 34b is provided with a dinitrogen monoxide source 34c, a mass flow controller 34d, and a valve 34e in this order from an upstream side to a downstream side along a gas flowing direction. Thus, a supply timing of dinitrogen monoxide from the dinitrogen monoxide source 34c is controlled by the valve 34e, and the flow of dinitrogen monoxide is adjusted to a predetermined flow rate by the mass flow controller 34d. Dinitrogen monoxide flows from the supply passage 34b to the gas supply pipe 34a, and is discharged from the gas supply pipe 34a into the processing chamber 10.

The chlorine supply 35 includes a gas supply pipe 35a inside the processing chamber 10, and a supply passage 35b outside the processing chamber 10. The supply passage 35b is provided with a chlorine source 35c, a mass flow controller 35d, and a valve 35e in this order from an upstream side to a downstream side along a gas flowing direction. Thus, a supply timing of chlorine from the chlorine source 35c is controlled by the valve 35e, and the flow of chlorine is adjusted to a predetermined flow rate by the mass flow controller 35d. Chlorine flows from the supply passage 35b to the gas supply pipe 35a, and is discharged from the gas supply pipe 35a into the processing chamber 10.

Each of the gas supply pipes 31a, 32a, 33a, 34a, and 35a is fixed to the manifold 17. Each of the gas supply pipes 31a, 32a, 33a, 34a, and 35a is formed of, for example, quartz. Each of the gas supply pipes 31a, 32a, 33a, 34a, and 35a extends linearly along the vertical direction at a position near the inner tube 11, and is bent in an L shape inside the manifold 17 to extend in the horizontal direction so as to penetrate the manifold 17. The gas supply pipes 31a, 32a, 33a, 34a, and 35a are arranged in the circumferential direction of the inner tube 11, and are formed at the same height.

A plurality of discharge ports 31f, 32f, 33f, 34f, and 35f are provided in respective portions of the gas supply pipes 31a, 32a, 33a, 34a, and 35a located inside the inner tube 11. The discharge ports 31f, 32f, 33f, 34f, and 35f are formed at predetermined intervals along the extending direction of the gas supply pipes 31a, 32a, 33a, 34a, and 35a. The discharge ports 31f, 32f, 33f, 34f, and 35f horizontally discharge gas toward the substrates W from the outer side in the radial direction of the substrates W. The discharge ports 31f, 32f, 33f, 34f, and 35f discharge gas parallel to the main surfaces of the substrates W. The interval between adjacent discharge ports is set to be the same as the interval between adjacent substrates W held by the boat 16, for example. The position of each discharge port in the height direction is set to an intermediate position between the adjacent substrates W that are adjacent to each other in the vertical direction. In this case, each discharge port can efficiently supply gas to the facing surfaces of the adjacent substrates W.

The gas supply 30 may mix a plurality of kinds of gases and discharge the mixed gas from a single gas supply pipe. The gas supply pipes 31a, 32a, 33a, 34a, and 35a may have mutually different shapes and arrangements. The gas supply 30 may further include a gas supply pipe configured to supply a different kind of gas, for example, an inert gas.

The exhaust 40 exhausts the gas that flows from the inner tube 11 through the opening 15, travels through a space Pl between the inner tube 11 and the outer tube 12, and is discharged via a gas outlet 41. The gas outlet 41 is formed in the side wall at an upper portion of the manifold 17 above the support 20. An exhaust passage 42 is connected to the gas outlet 41. A pressure regulating valve 43 and a vacuum pump 44 are successively provided in the exhaust passage 42, so that the gas inside of the processing chamber 10 can be exhausted.

The heater 50 is provided around the outer tube 12. The heater 50 is provided, for example, on a base plate 28. The heater 50 has a cylindrical shape so as to cover the outer tube 12. The heater 50 includes, for example, a heating element, and heats each of the substrates W inside the processing chamber 10.

The controller 90 is an electronic circuit such as a central processing unit (CPU), a field programmable gate array (FPGA), or an application specific integrated circuit (ASIC). The controller 90 performs various control operations described in the present specification by executing instruction codes stored in a memory or by being designed as a circuit for a special application.

### Operation of Film Forming Apparatus

The operation of the film forming apparatus 1 when performing the film forming method according to the embodiment will be described.

First, the controller 90 controls the elevator mechanism 25 to load the boat 16 holding the plurality of substrates W into the processing chamber 10, and closes the opening at the lower end of the processing chamber 10 with the lid 21 to seal the processing chamber 10 airtight. Then, the controller 90 controls the exhaust 40 to depressurize the inside of the processing chamber 10, and controls the heater 50 to adjust the temperature of the substrates W to the first temperature. Each of the substrates W may be the substrate 101 described above.

Next, the controller 90 controls the gas supply 30, the exhaust 40, and the heater 50 so as to perform the film forming method according to the embodiment for each of the substrates W accommodated in the processing chamber 10. In this manner, a recess 102 of each substrate 101 is filled with a silicon nitride film 104.

Next, the controller 90 raises the pressure inside the processing chamber 10 to the atmospheric pressure and lowers the temperature inside the processing chamber 10 to an unloading temperature, and then controls the elevator mechanism 25 to unload the boat 16 from the processing chamber 10.

As described above, the film forming method according to the embodiment can be performed by the film forming apparatus 1. In the above-described example, forming a silicon nitride film 104, forming an amorphous silicon film 105, removing the amorphous silicon film 105, and filling a recess with the silicon nitride film 104 are performed in the processing chamber 10 of the same film forming apparatus 1. However, some of the above processes may be performed in another apparatus.

While certain embodiments have been described, these embodiments have been presented by way of example only, and are not intended to limit the scope of the present disclosure. Indeed, the embodiments described herein may be embodied in a variety of other forms. Furthermore, various omissions, substitutions and changes in the form of the embodiments described herein may be made without departing from the spirit of the present disclosure. The accompanying claims and their equivalents are intended to cover such forms or modifications as would fall within the scope and spirit of the present disclosure.

In the above-described embodiments, an example in which the first silicon-containing gas is dichlorosilane has been described; however, the present disclosure is not limited thereto. As the first silicon-containing gas, dichlorosilane, hexachlorodisilane, trichlorosilane, monochlorosilane, trisilylamine, diiodosilane, triiodosilane, or any combination thereof can be used.

In the above-described embodiments, an example in which the second silicon-containing gas is disilane has been described; however, the present disclosure is not limited thereto. As the second silicon-containing gas, disilane, trisilane, or a combination thereof can be used.

In the above-described embodiments, an example in which the nitriding gas is ammonia has been described; however, the present disclosure is not limited thereto. As the nitriding gas, ammonia, diazene (N₂H₂), hydrazine (N₂H₄), monomethylhydrazine (CH₃(NH)NH₂), triethylamine, diethylamine, trimethylamine, dimethylamine, or any combination thereof can be used.

In the above-described embodiments, an example in which the impurity-containing gas is dinitrogen monoxide has been described; however, the present disclosure is not limited thereto. As the impurity-containing gas, an oxygen-containing gas, a phosphorus-containing gas, or a combination thereof can be used. Dinitrogen monoxide is an example of the oxygen-containing gas. As the phosphorus-containing gas, phosphine (PH₃) can be used.

In the above-described embodiments, an example in which the etching gas is chlorine has been described; however, the present disclosure is not limited thereto. As the etching gas, chlorine, hydrogen chloride (HCl), bromine (Br₂), hydrogen bromide (HBr), iodine (I₂), hydrogen iodide (HI), or any combination thereof can be used.

In the above-described embodiments, an example in which the processing chamber has a double-tube structure has been described; however, the present disclosure is not limited thereto. For example, the processing chamber may have a single-tube structure.

In the above-described embodiments, an example in which the film forming apparatus is an apparatus configured to supply gas from a gas supply pipe disposed along the longitudinal direction of the processing chamber and exhaust the gas from a slit disposed to face the gas supply pipe has been described; however, the present disclosure is not limited thereto. For example, the film forming apparatus may be an apparatus configured to supply gas from a gas supply pipe disposed along the longitudinal direction of the boat and exhaust the gas from a gas exhaust port disposed above the boat. For example, the film forming apparatus may be an apparatus configured to supply a processing gas from a gas supply pipe disposed below the processing chamber and exhaust the gas from a gas exhaust port disposed above the processing chamber.

In the above-described embodiments, an example in which the film forming apparatus is a batch-type apparatus configured to process a plurality of substrates at one time has been described; however, the present disclosure is not limited thereto. For example, the film forming apparatus may be a single-wafer type apparatus configured to process substrates one by one. For example, the film forming apparatus may be a semi-batch-type apparatus configured to process a plurality of substrates disposed on a rotation table by rotating the rotation table to allow each of the substrates to revolve and repeatedly pass through processing gas supply regions disposed along the radius direction of the rotation table.

According to one embodiment of the present disclosure, the occurrence of seams when a recess is filled with a silicon nitride film can be reduced.

What is claimed is:

1. A film forming method comprising:
(a) preparing a substrate having a recess in a surface thereof;
(b) forming a silicon nitride film in the recess;
(c) forming an amorphous silicon film in the recess;
(d) removing the amorphous silicon film; and
(e) filling the recess with the silicon nitride film after the (d) removing the amorphous silicon film, wherein
the amorphous silicon film is formed such that step coverage of the amorphous silicon film is lower than step coverage of the silicon nitride film, and
the (c) forming the amorphous silicon film is performed one or more times during the (b) forming the silicon nitride film.

2. The film forming method according to claim 1, wherein the (c) forming the amorphous silicon film is performed two or more times during the (b) forming the silicon nitride film.

3. The film forming method according to claim 2, wherein the (c) forming the amorphous silicon film is started before the silicon nitride film is formed on the amorphous silicon film in the (b) forming the silicon nitride film.

4. The film forming method according to claim 1, wherein the (b) forming the silicon nitride film includes alternately supplying a first silicon-containing gas and a nitriding gas to the substrate.

5. The film forming method according to claim 1, wherein the (c) forming the amorphous silicon film is stopped before the amorphous silicon film is formed on the silicon nitride film formed on a bottom surface of the recess.

6. The film forming method according to claim 1, wherein the (c) forming the amorphous silicon film includes simultaneously supplying a second silicon-containing gas and an impurity-containing gas to the substrate.

7. The film forming method according to claim 6, wherein the (c) forming the amorphous silicon film includes supplying the impurity-containing gas without supplying the second silicon-containing gas to the substrate after the simultaneous supplying of the second silicon-containing gas and the impurity-containing gas.

8. The film forming method according to claim 7, wherein the impurity-containing gas is an oxygen- containing gas or a phosphorus-containing gas.

9. The film forming method according to claim 1, wherein
the (d) removing the amorphous silicon film includes supplying an etching gas to the substrate, and
the etching gas is a gas having an etching rate for the amorphous silicon film higher than an etching rate for the silicon nitride film.

10. The film forming method according to claim 9, wherein the etching gas is chlorine (Cl₂).

11. The film forming method according to claim 1, wherein the (b) forming the silicon nitride film, the (c) forming the amorphous silicon film, the (d) removing the amorphous silicon film, and the (e) filling the recess are performed in a same processing chamber.

12. A film forming apparatus comprising:
a processing chamber;
a gas supply configured to supply a processing gas into the processing chamber; and
a controller, wherein
the controller is configured to perform:
(a) preparing a substrate having a recess in a surface thereof;
(b) forming a silicon nitride film in the recess;
(c) forming an amorphous silicon film in the recess;
(d) removing the amorphous silicon film; and
(e) filling the recess with the silicon nitride film after the (d) removing the amorphous silicon film, wherein
the amorphous silicon film is formed such that step coverage of the amorphous silicon film is lower than step coverage of the silicon nitride film, and
the (c) forming the amorphous silicon film is performed one or more times during the (b) forming the silicon nitride film.
